(19) United States
(12) Patent Application Publication
(10) Pub. No.: US 2002/0024333 A1
(43) Pub. Date: Feb. 28, 2002

(54) Current sensor

(76) Inventor: Hubert Maiwald, Salching (DE)

Correspondence Address: Kevin R. Spivak, Morrison & Foerster LLP, Suite 5500, 2000 Pennsylvania Avenue, N.W., Washington, DC, 20006-1888, US

(21) Appl. No.: 09/900,452

(22) Filed: Jul. 9, 2001

Related U.S. Application Data
(60) Provisional application No. 60/216,685, filed on Jul. 7, 2000.

(51) Int. Cl. G01R 33/00

(52) U.S. Cl. 324/117 R

(57) ABSTRACT

The current sensor has at least one magnetic field sensor for measuring a current in a conductor by determining the strength of the magnetic field produced by the current. Furthermore, the current sensor has an arrangement for focussing and guiding the magnetic field toward the magnetic field sensor. The arrangement has at least two mutually opposite sections, between which the magnetic field sensor is arranged. The arrangement is composed of a magnetic material which has a coercivity strength of less than 10 A/cm.

### TECHNICAL FIELD OF THE INVENTION

The invention relates to a current sensor and a use of such a current sensor.

### BACKGROUND OF THE INVENTION

A variety of current sensors are well known in the conventional arts. A first current sensor comprises a slotted annular core composed, for example, of ferrite. In order to measure a current (primary current) through a primary conductor, the annular core surrounds the primary conductor. The current through the primary conductor produces a magnetic field, which is focussed by the annular core. A magnetic field sensor is arranged in the air gap in the slotted annular core. The magnetic field sensor controls a considerably smaller current (secondary current) than the primary current through a secondary winding, which is wound around the annular core, in such a way that the magnetic field in the air gap is zero. The primary current is thus measured by determining the secondary current. The measurement range of the first current sensor is limited by the saturation magnetization of the annular core and the maximum power loss in the secondary winding.

A second current sensor comprises a shunt resistor. The resistor is fitted in the conductor whose current is to be measured, so that the current flows through the resistor. The current is measured by determining the voltage drop across the resistor.

### SUMMARY OF THE INVENTION

In one embodiment of the invention, there is a current sensor. The current sensor includes, for example, at least one magnetic field sensor to measure a current in a conductor by determining the strength of a magnetic field produced by the current and a unit to focus and guide the magnetic field toward the at least one magnetic field sensor, in which the unit has at least two mutually opposite sections, between which the magnetic field sensor is arranged, and in which the unit comprises magnetic material which has a coercivity field strength of less than about 10 kA/cm.

In one aspect of the invention, the current sensor includes two sections of the unit which each have one end surface. The end surfaces of the sections run substantially parallel to one another, and depending on the distance between the sections, the end surfaces are larger than a cross section, parallel to the end surfaces, of the at least one magnetic field sensor in such a way that the magnetic field is substantially homogeneous in the region of the at least one magnetic field sensor.

In another aspect of the invention, the current sensor includes two additional opposite sections between which another magnetic field sensor is arranged, and the unit is designed in such a way that, when measuring a current in the conductor, the direction of the magnetic field in the region of the at least one magnetic field sensor is substantially opposite the direction of a magnetic field in the region of another magnetic field sensor.

In yet another aspect of the invention, the unit of the current sensor includes two strips arranged parallel to one another.

In still another aspect of the invention, the unit of the current sensor includes a double-slotted ring.

In another aspect of the invention, the current sensor remains in the region of the conductor for a period of time during which both low currents of less than 100 mA and high currents of more than 1000 A flow through the conductor, and during which the low currents are measured using the current sensor.

In still another aspect of the invention, the conductor of the current sensor is connected to a battery or a generator in an automobile, and in which currents from the battery are measured using the current sensor when the automobile is not being driven.

In another embodiment of the invention, the method for using a current sensor includes measuring a current in a conductor by determining the strength of a magnetic field produced by the current; and focusing and guiding the magnetic field toward a magnetic field sensor, in which the magnetic field sensor is arranged between two mutually opposite sections of a focusing and guiding unit.

In another aspect of the invention, the method for using a current sensor includes measuring low currents during the time period when both low currents of less than 100 mA and high currents of more than 1000 A flow through the conductor.

### BRIEF DESCRIPTION OF THE DRAWINGS

Exemplary embodiments of the invention will be explained in more detail in the following text with reference to the figures, in which:

FIG. 1 shows a cross section through a first current sensor, which surrounds a first conductor.

FIG. 2 shows a view of the first current sensor, showing the second conductor plate, the first conductor and the lines.

FIG. 3 shows a cross section through a second current sensor, which surrounds a second conductor.

### DETAILED DESCRIPTION OF THE PREFERRED EMBODIMENTS

With the present-day development of new batteries with higher voltages in automobile engineering, it is desirable to measure the current from the battery very accurately when the automobile is not being driven. This desire is at least partially driven by the effort to be able to react to leakage currents and to better diagnose the condition of the battery accurately to help reduce power loss.

In one embodiment of the invention, there is a current sensor which is suitable for remaining in the region of a conductor for a period of time and for measuring low currents through the conductor although very high currents will also flow through the conductor within this period of time.

Very high currents, for example 1000 A, at times flow out of the battery when the automobile is being driven. The measurement range of the current sensor should thus preferably extend from 1 A to 100 A. Previous current sensors are unsuitable for achieving this. In the first current sensor described above, the primary current when the automobile being driven is so high that the annular core is subjected to irreversible remanence. As a result, the accuracy of the first current sensor is greatly reduced such that low currents can no longer reliably be measured when the automobile is subsequently not being driven. In the second current sensor described above, the primary current when the automobile is being driven is so high that the energy and voltage losses in the resistor are unacceptable when designed for a measurement range up to 100 A.

In another embodiment of the invention, there is a current sensor having at least one magnetic field sensor for measuring a current in a conductor by determining the strength of the magnetic field produced by the current. The strength of the magnetic field is thus a measure of the current level. The current sensor also has an arrangement (i.e. unit) for focussing and guiding the magnetic field toward the magnetic field sensor. The arrangement has at least two mutually opposite sections, between which the magnetic field sensor is arranged. The arrangement is composed of a magnetic material which has a coercivity field strength of less than 10 kA/cm. Owing to the focussing function of the arrangement, the magnetic field is amplified at the location of the magnetic field sensor. The signal-to-noise ratio is thus improved, for example, by a factor of ten. Furthermore, the arrangement produces shielding against external fields. This effect also improves the signal-to-noise ratio. The current sensor is thus suitable for measuring low currents.

Owing to the low coercivity field strength of the material of the arrangement, the material has very soft magnetic properties. For example, the material contains MU metal (such as Vacoperm (VAC Hanau) or Magnifier (Krupp VDM)) transformer lamination or similar NiFe alloys. Such materials have scarcely any magnetic remanence. Thus, although very high current can flow at times, the accuracy of the current sensor according to the invention is not adversely affected, and it has the required sensitivity for low currents.

The material of the arrangement, in the preferred embodiment, should not have a rectangular hysteresis loop. Preferably, the two sections of the arrangement each have one end surface, with the end surfaces of the sections running parallel to one another. Depending on the distance between the sections, the end surfaces are larger than a cross section, parallel to the end surfaces, of the magnetic field sensor in such a way that the magnetic field is essentially homogeneous in the region of the magnetic field sensor. As a result of this geometry of the arrangement, the magnetic field is homogeneous over a much larger region than in the case of a current sensor without an arrangement. Consequently, the arrangement of the magnetic field sensor with regard to the conductor is less position critical, since slight radial discrepancies from the nominal position will not likely influence the accuracy of the current sensor as well.

A current sensor is particularly sensitive for low currents when two additional mutually opposite sections between which a further magnetic field sensor is arranged. The arrangement in this case is designed in such a way that, when measuring a current in a conductor, the direction of the magnetic field in the region of the magnetic field sensor is essentially in the opposite direction of the magnetic field in the region of the additional magnetic field sensor. During operation of such a current sensor, the difference between the output signals from the two magnetic field sensors is formed, which represents the measure of the level of the current through the conductor. Since the magnetic field produced by the current to be measured in the region of one of the magnetic field sensors points in a direction which is in the opposite direction of the magnetic field produced in the region of the other magnetic field sensor, formation of the difference doubles the signal strength, resulting in an improvement in the signal-to-noise ratio. Since, with such an arrangement, external fields normally point substantially in the same direction in the region of both magnetic field sensors, they cancel each other out when the difference is formed. This results in a further major increase in the signal-to-noise ratio. Overall, the signal-to-noise ratio can be increased by a factor of more than 1000 in comparison to the signal-to-noise ratio of a single magnetic field sensor without an arrangement.

By way of example, the conductor is arranged between the magnetic field sensor and the magnetic field sensor. The current sensor, in this example, comprises two strips arranged parallel to one another and can be easily manufactured. Such a current sensor is preferably positioned around a conductor in the form of a strip. A homogeneous magnetic field is achieved if the strips are thickened in the region of the magnetic field sensor, or of each magnetic field sensor. Alternatively, the arrangement may comprise, for example, a double-slotted ring. That is, the arrangement may include two ring halves. Such a current sensor is particularly suitable for measuring currents through a conductor having a round cross section.

The arrangement may be produced, for example, by rolling or forming an alloy. In one embodiment, the current sensor remains in the region of a conductor for a period of time and measures low currents, for example currents of less than 100 mA through the conductor, with very high currents, for example of more than 1000 A, also flowing through the conductor within the period of time. By way of example, the current sensor is installed in the region of a conductor which is connected to a battery or a generator in an automobile. The current sensor remains in the region of the conductor for a period of time during which the automobile is being driven and for a period of time during which the automobile is not being driven. The current from the battery is measured using the current sensor when the automobile is not being driven in order, for example, to be able to react to leakage currents or in order to be able to diagnose the condition of the battery accurately.

For use in automobiles, the current sensor should not be temperature-sensitive, since the temperatures at the installation point of the current sensor may reach up to 1500 C. when the automobile is being driven. The permeability of soft-magnetic material may vary by a factor of 10 between −40 and +1500 C. However, it has been found that the temperature dependency of the permeability does not noticeably change the measurement result of the current sensor. This is due to the fact that the magnetic field sensor is arranged in the air gap where the permeability is approximately uniform, and the soft-magnetic material may have a permeability of approximately 50,000 at approximately 250 C. The measured magnetic field is given by the formula

B=d

where

I=current through the conductor

D=distance between the two mutually opposite sections between which the magnetic field sensor is arranged

L=iron length

p=permeability constant

AR=relative permeability.

It can be seen that the second term in the denominator can be ignored if AR is large. Consequently, since the permeability of the soft-magnetic material is generally very high, it is not significant if temperature fluctuations cause the permeability to change by a factor of 4 to 10. The magnetic field sensor may be, for example, a Hall sensor. Insulation may be provided between the conductor and the arrangement.

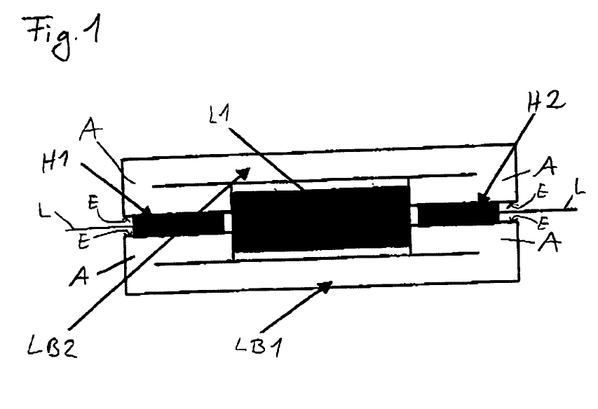

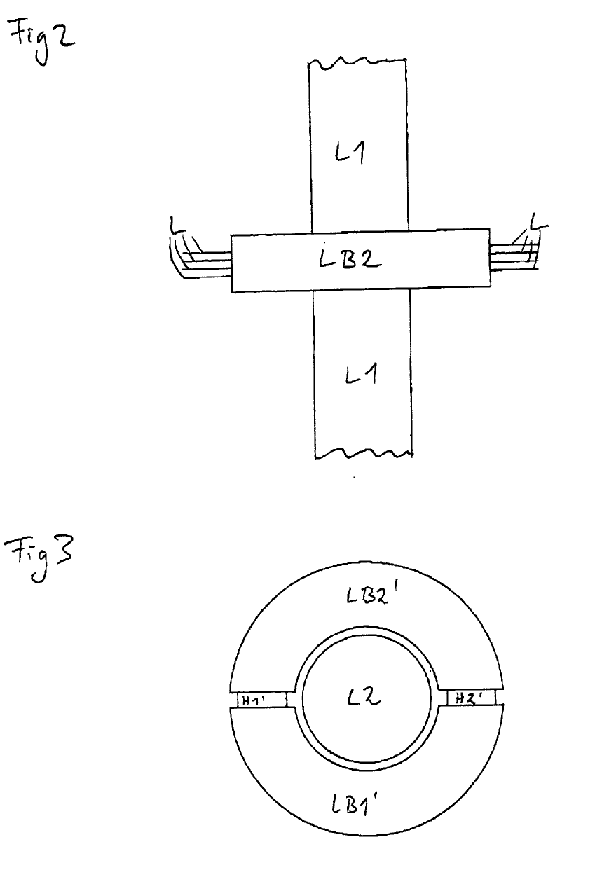

In an exemplary embodiment, a first current sensor is produced in order to measure a current through a first conductor Ll. A first conductor plate LB1 is formed by folding an approximately 1 mm thick, approximately 5 mm wide and approximately 30 mm long strip of Mu metal symmetrically at both ends so that the strip then has a length of only approximately 20 mm (see FIG. 1). A second conductor plate LB2 is produced in the same way (see FIGS. 1 and 2).

The first conductor L1 is placed between the thickened sections A of the first conductor plate LB1 (see FIGS. 1 and 2). The first conductor L1 is in the form of a strip, and has a thickness of approximately 2 mm and a width of approximately 10 mm. A first Hall sensor H1 and a second Hall sensor H2 are connected to lines L (see FIG. 2) and are arranged on end surfaces E of the sections A of the first conductor plate LB1 in such a way that the first conductor L1 is arranged centrally between the first Hall sensor H1 and the second Hall sensor H2 (see FIG. 1). The end surfaces E are considerably larger than the cross sections, parallel to the end surfaces E, through the first Hall sensor H1 and the second Hall sensor H2 (see FIG. 1).

The second conductor plate L2 is then arranged on the first conductor L1 and the first Hall sensor H1 and the second Hall sensor H2 in such a way that the first conductor plate LB1 and the second conductor plate LB2 form a symmetrical arrangement, in which the end surfaces E of the sections A of the first conductor plate L1 and of the second conductor plate L2 run parallel to one another and are opposite one another in such a way that the first Hall sensor H1 and the second Hall sensor H2 are each arranged between two of the end surfaces E.

In a second exemplary embodiment, a second current sensor is provided which is constructed similarly to the first current sensor with a first Hall sensor H1 ′ and a second Hall sensor H2′, with the difference that the first conductor plate LB1′ and the second conductor plate LB2′ are in the form of half rings. Furthermore, the second conductor L2, which is surrounded by the arrangement formed by the first conductor plate LB1′ and the second conductor plate LB2′, has a round cross section (see FIG. 3).

What is claimed is:

1. A current sensor, comprising:
at least one magnetic field sensor to measure a current in a conductor by determining the strength of a magnetic field produced by the current; and
a unit to focus and guide the magnetic field toward the at least one magnetic field sensor, in which the unit has at least two mutually opposite sections, between which the magnetic field sensor is arranged, and in which the unit comprises magnetic material which has a coercivity field strength of less than about 10 kA/cm.

2. The current sensor as claimed in claim 1, wherein
the two sections of the unit each have one end surface, in which the end surfaces of the sections run substantially parallel to one another, and
depending on the distance between the sections, the end surfaces are larger than a cross section, parallel to the end surfaces, of the at least one magnetic field sensor in such a way that the magnetic field is substantially homogeneous in the region of the at least one magnetic field sensor.

3. The current sensor as claimed in claim 1, wherein the unit further comprises:
two additional opposite sections between which another magnetic field sensor is arranged, and
the unit is designed in such a way that, when measuring a current in the conductor, the direction of the magnetic field in the region of the at least one magnetic field sensor is substantially opposite the direction of a magnetic field in the region of another magnetic field sensor.

4. The current sensor as claimed in claim 3, in which the unit comprises two strips arranged parallel to one another.

5. The current sensor as claimed in claim 3, in which the unit comprises a double-slotted ring.

6. The current sensor as claimed in claim 1, wherein the current sensor remains in the region of the conductor for a period of time during which both low currents of less than 100 mA and high currents of more than 1000 A flow through the conductor, and during which the low currents are measured using the current sensor.

7. The current sensor as claimed in claim 6, in which the conductor is connected to a battery or a generator in an automobile, and in which currents from the battery are measured using the current sensor when the automobile is not being driven.

8. A method for using a current sensor, comprising:
measuring a current in a conductor by determining the strength of a magnetic field produced by the current; and
focusing and guiding the magnetic field toward a magnetic field sensor, in which the magnetic field sensor is arranged between two mutually opposite sections of a focusing and guiding unit.

9. The method of claim 8, further comprising:
measuring low currents during the time period when both low currents of less than 100 mA and high currents of more than 1000 A flow through the conductor.
